(19) United States
(12) Patent Application Publication
(10) Pub. No.: US 2003/0168738 A1
(43) Pub. Date: Sep. 11, 2003

(54) Socketable IC package and associated methods

(75) Inventors: Ashok N. Kabadi, Portland, OR (US); Harry L. Hampton III, Aloha, OR (US)

Correspondence Address: Schwegman, Lundberg, Woessner & Kluth, P.A., P.O. Box 2938, Minneapolis, PA, 55402, US

(73) Assignee: Intel Corporation

(21) Appl. No.: 10/093,905

(22) Filed: Mar. 8, 2002

(51) Int. Cl. H01L 23/48

(52) U.S. Cl. 257/738

(57) ABSTRACT

To decrease the thickness and bulk of an electronic assembly, the connectors of an integrated circuit (IC) package are releaseably coupled to corresponding receptors of an underlying substrate. In one embodiment, an IC package having ball-grid-array (BGA) connectors is mounted on a socketable substrate having mating receptors. The BGA balls are formed of gold-plated copper. The ball/receptor interface requires a minimum of vertical insertion or removal force and provides a gas-tight contact. Methods of fabrication, as well as application of the electronic assembly to a data processing system, are also described.

### TECHNICAL FIELD

Embodiments of the present invention relate generally to electronics packaging and, more particularly, to a socketable integrated circuit package and to manufacturing methods related thereto.

### BACKGROUND INFORMATION

Integrated circuits (ICs) have typically been assembled into electronic packages by physically and electrically coupling them to a substrate made of organic or ceramic material. One or more such IC packages can be physically and electrically coupled to a secondary substrate such as a printed circuit board (PCB) or motherboard to form an “electronic assembly”. The “electronic assembly” can be part of an “electronic system”. An “electronic system” is broadly defined herein as any product comprising an “electronic assembly”. Examples of electronic systems include computers (e.g., desktop, laptop, hand-held, server, etc.), wireless communications devices (e.g., cellular phones, cordless phones, pagers, etc.), computer-related peripherals (e.g., printers, scanners, monitors, etc.), entertainment devices (e.g., televisions, radios, stereos, tape and compact disc players, video cassette recorders, MP3 (Motion Picture Experts Group, Audio Layer 3) players, etc.), and the like.

In the field of electronic systems there is an incessant competitive pressure among manufacturers to drive the performance of their equipment up while driving down production costs. This is particularly true regarding the packaging of ICs, where each new generation of packaging must provide increased performance, at reduced cost, while generally being smaller or more compact in size. As market forces drive equipment manufacturers to produce electronic systems with increased performance and decreased size, IC packaging accordingly also needs to support these requirements.

In addition, manufacturers of high-end IC packages, such as processors, are experiencing increasing demand for IC packages mounted in thin, light-weight packaging, because such packaging is useful for many applications. For example, hand-held and portable electronic systems, such as cellular telephones, palm-top computers, laptop computers, personal digital assistants, calculators, MP3 players, watches, hearing aids, and similar equipment typically requires ICs in thin, light-weight packages.

Surface mount technology (SMT) is a widely known technique for coupling ICs to a substrate. One of the conventional methods for surface-mounting an IC on a substrate employs a ball-grid-array (BGA). In fabricating a BGA package, the electrically conductive terminals of an IC component are soldered directly to corresponding lands on the surface of the substrate using reflowable solder bumps or balls.

In addition to using SMT to couple an individual IC die to a substrate, it is also well known to use SMT to couple an IC package to a substrate such as a printed circuit board (PCB) or motherboard. Solder bumps, for example, can be employed between lands on the IC package and corresponding lands on the PCB.

It is known in the art to connect an IC package to an interposer that can be easily inserted and removed from an underlying socket structure, as shown in FIG. 1.

FIG. 1 is a side view representation of an electronic system 1 incorporating a prior art socketable electronic assembly 6. Electronic assembly 6 comprises an IC package 2 and an interposer 10. To the top of IC package 2 is typically mounted a heat sink or integrated heat spreader 8. The underside of IC package 2 has a plurality of solder balls 4 mounted to corresponding pads 12 of interposer 10. Interposer 10 has a plurality of projecting contacts or pins 14. Pins 14 can be in a pin-grid-array (PGA). Pins 14 are typically thin and easily bent. The combined electronic assembly 6, comprising IC package 2 and interposer 10, can be removeably mounted on socket 16 by inserting pins 14 into receptacles 18 in the upper surface of socket 16. Socket 16 has a plurality of lands 20, each of which has a corresponding solder ball 22. Socket 16 can be mounted upon a printed circuit board (PCB) such as motherboard 24 by affixing the solder balls 22 of socket 16 to corresponding pads 26 on the upper surface of motherboard 24.

It is also known in the art, as shown, for example, in U.S. Pat. No. 6,045,416, to removeably insert solder balls of a BGA IC package into corresponding ball-receiving receptacles of an underlying socket structure. However, this arrangement has several disadvantages, including the fact that the solder balls deform or “cold flow” over time under the pressure of the ball-receiving receptacles, increasing the likelihood of high-resistance connections and open circuits.

For the reasons stated above, and for other reasons stated below which will become apparent to those skilled in the art upon reading and understanding the present specification, there is a significant need in the art for apparatus and methods for packaging an IC that minimize the thickness and weight of the packaging, and that increase reliability.

### BRIEF DESCRIPTION OF THE DRAWINGS

FIG. 1 is a side view representation of an electronic system incorporating a prior art socketable electronic assembly;

FIG. 2 is a side view representation of an electronic system incorporating a socketable IC package, in accordance with one embodiment of the invention;

FIG. 3 is a side view of a socketable IC package, in accordance with one embodiment of the invention;

FIG. 4 is a top view of a socketable IC package, in accordance with one embodiment of the invention;

FIG. 5 is a side view of an IC package and a ball carrier, in accordance with one embodiment of the invention;

FIG. 6 is a perspective view of an IC package and a ball carrier, in accordance with one embodiment of the invention;

FIG. 7 is a cross-sectional view of an electronic system comprising an IC package, a substrate or socket, and a secondary substrate or motherboard, in accordance with one embodiment of the invention;

FIG. 8 is a cross-sectional view of an electronic system comprising an IC package, a substrate or socket, and a secondary substrate or motherboard, in accordance with another embodiment of the invention;

FIG. 9 is a perspective view of two balls of a socketable IC package coupled to a pair of receptacles of a socket apparatus (not shown), in accordance with one embodiment of the invention;

FIG. 10 is a perspective view of several receptacles and a substrate or socket, in accordance with one embodiment of the invention;

FIG. 11 is a top view of several receptacles partially embedded within a substrate or socket, in accordance with one embodiment of the invention;

FIG. 12 is a perspective view of a three-pronged receptacle, in accordance with one embodiment of the invention;

FIG. 13 is a perspective view of a four-pronged receptacle, in accordance with one embodiment of the invention;

FIG. 14 is a block diagram of an electronic system 270 incorporating at least one electronic assembly 274 with a socketable IC package in accordance with one embodiment of the invention;

FIGS. 15A and 15B together constitute a flow diagram illustrating methods of fabricating an electronic assembly comprising relatively hard conductive balls, in accordance with one or more embodiments of the invention; and

FIG. 16 is a flow diagram illustrating methods of positioning a plurality of conductive balls on an IC package, in accordance with one or more embodiments of the invention.

### DETAILED DESCRIPTION OF EMBODIMENTS OF THE INVENTION

In the following detailed description of embodiments of the invention, reference is made to the accompanying drawings that form a part hereof, and in which is shown by way of illustration, but not of limitation, specific embodiments of the invention. These embodiments are described in sufficient detail to enable those skilled in the art to understand and implement them, and it is to be understood that other embodiments may be utilized and that mechanical, chemical, structural, electrical, and procedural changes may be made without departing from the spirit and scope of the present disclosure. The following detailed description is, therefore, not to be taken in a limiting sense, and the scope of embodiments of the present invention is defined only by the appended claims.

Disclosed herein is a solution to thickness, weight, and/or reliability limitations in an IC package, and to loop induction problems that are associated with prior art IC packages, by mounting an IC package directly on a socket. In one embodiment, an IC package has electrical contacts on its bottom surface in the form of relatively hard copper balls. In one embodiment, the copper balls are first plated with nickel and then with gold. The copper balls fit into corresponding electrically conductive receptacles within the upper surface of a socket structure. The receptacles can be implemented in various shapes, and they can be secured within the socket in different ways. In one embodiment, each receptacle comprises a plurality of finger-like members that deflect as the ball is inserted into the receptacle. The receptacle fingers provide a cleaning wipe of the ball surface as the ball is inserted. The receptacle fingers also provide a gas-tight connection to the ball surface. When mounting the copper balls to the underside of the IC package, a ball carrier is utilized to keep the outer surface of each ball, i.e. the surface to be received by the receptacle, free of solder. Various embodiments are illustrated and described herein, including methods of fabrication, as well as application of the socketable IC package to an electronic assembly, an electronic system, and a data processing system.

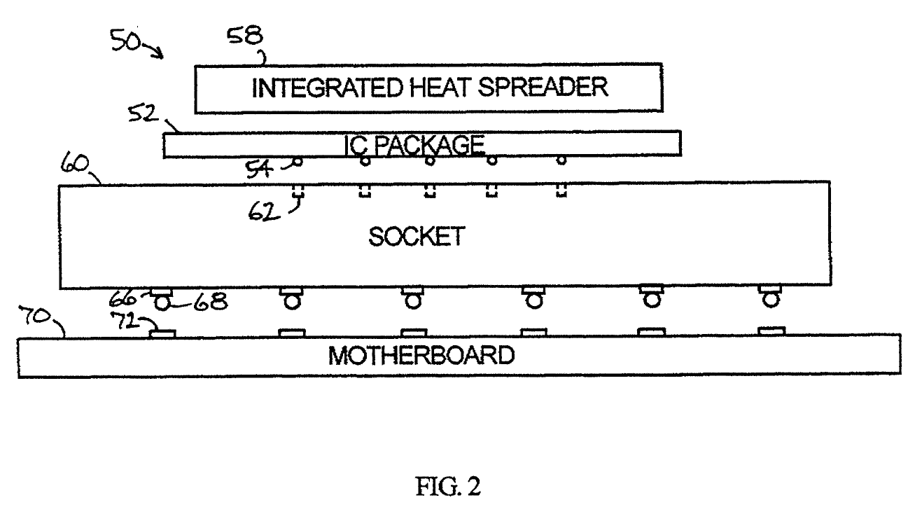

FIG. 2 is a side view representation of an electronic system 50 incorporating a socketable IC package 52, in accordance with one embodiment of the invention. IC package 52 comprises a die (not shown) having a plurality of terminals (not shown). The die can be any type of IC, such as a processor, memory chip, chipset component, or the like. In a conventional manner, the die is mounted on an IC substrate to form IC package 52. The IC substrate can be a conventional organic land grid array (OLGA) substrate, for example.

IC package can have a heat sink or integrated heat spreader (IHS) 58 on its upper surface. However, this is not essential, and the IC package could be used without cooling or with another type of cooling mechanism, depending upon the type of IC and the overall packaging design.

IC package 52 comprises a plurality of relatively hard conductive leads or balls 54 on its lower surface. Each of balls 54 is electrically coupled to a respective one of the plurality of terminals (not shown) of the die (not shown) within IC package 52. Although, in one embodiment, the leads on the lower surface of IC package 52 are balls 54, they could have different shapes in other embodiments. For example, they could have one or more flat sides. They could be cylindrical or prong-like. In another embodiment, a combination of different types of leads could be used.

The term “relatively hard”, as used herein, means having a minimum hardness of B-45 on the Rockwell hardness scale. For example, balls 54 can comprise aluminum, copper, magnesium, molybdenum, platinum, silver, and zinc. Balls 54 could also be formed of material comprising alloys of the foregoing metals. Balls 54 could also comprise steel or a phosphor-bronze alloy.

In one embodiment, balls 54 are formed of copper 0.030 inches (0.762 mm) in diameter, plated first with 150 micro-inches (3.81 micrometers) of nickel and then with 30 micro-inches (0.762 micrometers) of gold. Any other suitable coating or combination of coatings can be used, including cobalt, palladium, and silver. The coating(s) should be electrically conductive and should preferably have a minimum hardness of 90 on the Knoop hardness scale.

“Suitable”, as used herein, means having characteristics that are sufficient to produce the desired result(s). Suitability for the intended purpose can be determined by one of ordinary skill in the art using only routine experimentation.

To mount IC package 52 on underlying socket 60, the plurality of balls 54 are inserted into a corresponding plurality of mating, conductive receptacles 62 in the upper surface of socket 60. The balls and receptacles are described in greater detail below.

Continuing with the description of FIG. 2, socket 60 can be any type of socketing apparatus, including a zero-insertion-force (ZIF) or low-insertion-force (LIF) socket. In one embodiment, socket 60 comprises an insulating member formed of a suitable insulating material, such as polyphenylene sulphide (PPS) or liquid crystal polymer (LCP).

Socket 60 has a plurality of receptacles 62 in its upper surface. Receptacles 62 are electrically coupled to a corresponding plurality of terminals 66 on its lower surface. Socket 60 can be a multilayer substrate comprising multiple layers of internal conductors such as traces and vias, or socket 60 could be a single-layer substrate. Each terminal 66 can be electrically and physically coupled to a corresponding land 72 of a printed circuit board (PCB) or motherboard 70. In one embodiment, terminals 66 are coupled to lands 72 through solder balls 68, but in other embodiments different connectors could be used, such as pin-type connectors, compression connectors, or the like.

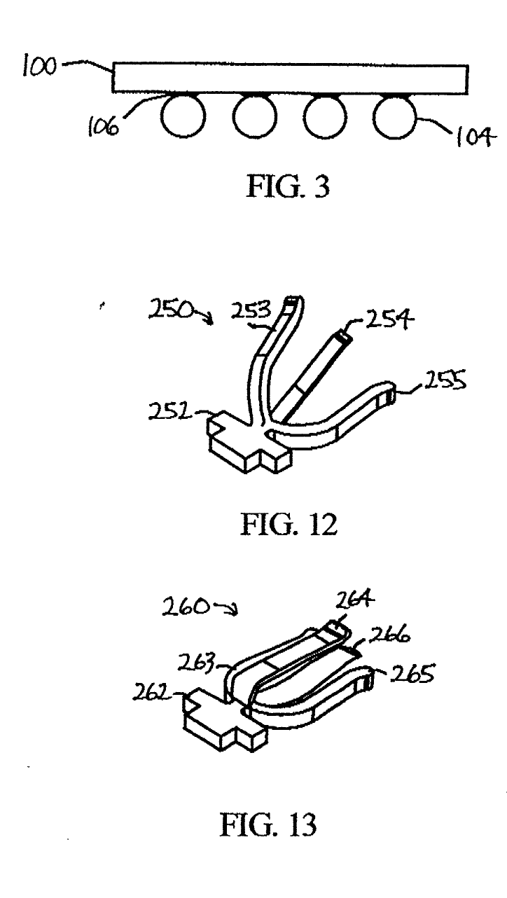

FIG. 3 is a side view of a socketable IC package 100, in accordance with one embodiment of the invention. IC package 100 comprises a die (not shown) mounted on and/or within a package substrate or housing. IC package 100 can be of any type. On the lower surface of IC package 100 are a plurality of relatively hard conductive balls 104. In one embodiment, each conductive ball 104 is electrically and physically coupled to a corresponding terminal (not shown) of IC package 100 through a solder fillet 106.

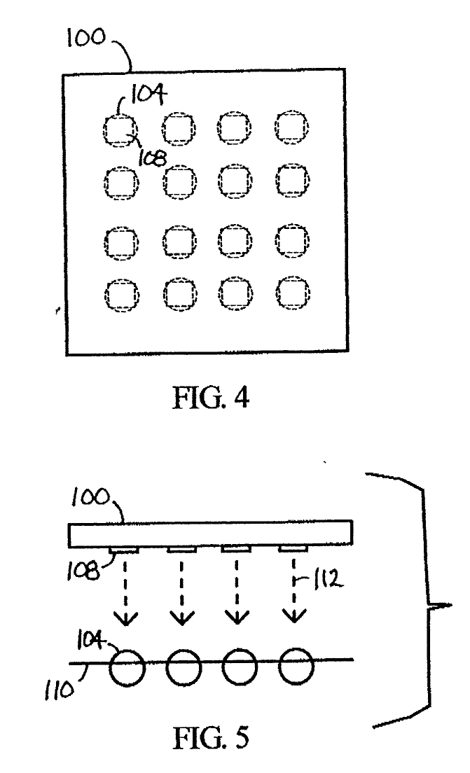

FIG. 4 is a top view of a socketable IC package 100, in accordance with one embodiment of the invention. In FIG. 4, we are looking down on the top of IC package 100 and through IC package 100 at balls 104 (shown in dashed outline) on the underside of IC package 100. Each ball 104 is electrically and physically coupled to a corresponding terminal 108 (shown in dashed outline) of IC package 100.

FIG. 5 is a side view of an IC package 100 and a ball carrier 110, in accordance with one embodiment of the invention. To ensure correct alignment of the plurality of balls 104 with their respective terminals 108 of IC package 100, and to keep the lower contact surfaces (i.e. the portion of balls 104 below carrier 110, as viewed in FIG. 5) of balls 104 free of solder, in one embodiment a carrier 110 is used. Carrier 110 can be formed of any suitable material, such as polyimide. In one embodiment, a polyimide marketed under the trademark Kapton by E. I. du Pont de Nemours & Co. was used. Other possible materials for carrier 110 include polyester, epoxy, and fiberglass. In one embodiment, carrier 110 has a thickness of approximately 0.003 inches (0.076 mm). However, in other embodiments, thicker or thinner material could be used. In general, the thickness of carrier 110 should be such that carrier 110 can be readily removed without dislodging balls 104.

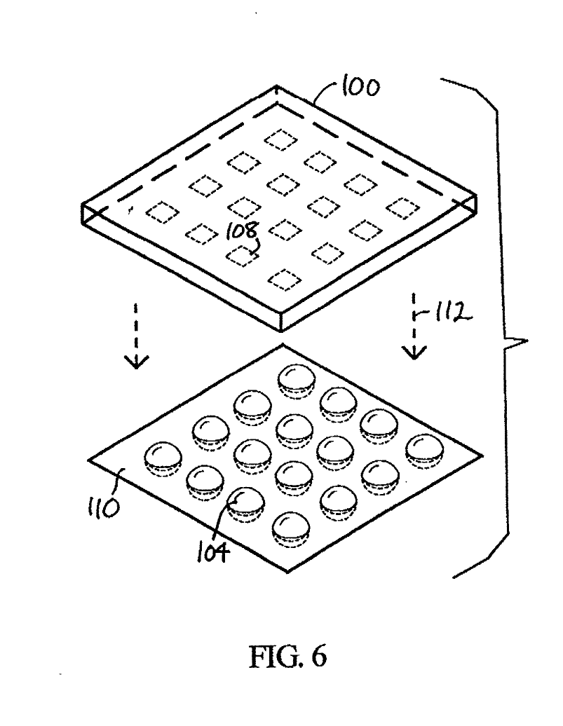

Carrier 110 comprises a planar member having a plurality of circular apertures (refer also to FIG. 6). The circular apertures of carrier 110 have a uniform diameter that is less than the diameter of balls 104, so that balls 104 will not pass through the apertures, and only the upper portions of balls 104 extend through the apertures in carrier 110. In one embodiment, the diameter of the apertures of carrier 110 is 0.015 inches (0.38 mm); however, in other embodiments, it could be longer or shorter.

Still referring to FIG. 5, the terminals 108 of IC package 100 are coupled to balls 104 by moving IC package 100 in the direction of arrows 112 while maintaining proper registration of terminals 108 with balls 104. Alternatively, carrier 110 could be moved towards IC package 100 to match up balls 104 with terminals 108. In one embodiment, balls 104 are electrically and physically joined to terminals 108 via solder. Any suitable solder process can be used. For example, prior to registration, the mating surfaces of balls 104 and/or terminals 108 could be coated with solder paste, and after proper registration, the assembly could be subjected to sufficient heat to melt the solder. During the solder reflow operation, carrier 110 shields the lower contact surfaces of balls 104 from solder contamination. Following solder reflow, the carrier 110, which is relatively thin and flexible, can be readily pulled away from the balls 104, with the circular apertures of the carrier 110 stretching open as they pass over the balls 104.

Alternative arrangements of the carrier 110 are possible. For example, the carrier 110 could be disposed beneath the balls 104, as viewed in FIG. 5, rather than above the balls 104.

FIG. 6 is a perspective view of an IC package 100 and a ball carrier 110, in accordance with one embodiment of the invention. FIG. 6 shows essentially the same process of registering balls 104 with terminals 108 of IC package 100, as is shown in FIG. 5 discussed above. From FIG. 6 it will be seen that the pitch and placement of the apertures within carrier 110 match those of the pads or terminals of IC substrate 100.

To facilitate retention of balls 104 within carrier 110 during the manufacturing process, balls 104 can be held within the apertures of carrier 110 with an adhesive coating. In one embodiment, the adhesive is a water-soluble epoxy. After balls 104 are affixed to terminals 108, e.g. through soldering, carrier 110 can be removed, and any adhesive residue can be removed from balls 104, e.g. through rinsing in a suitable solvent, such as dionized water.

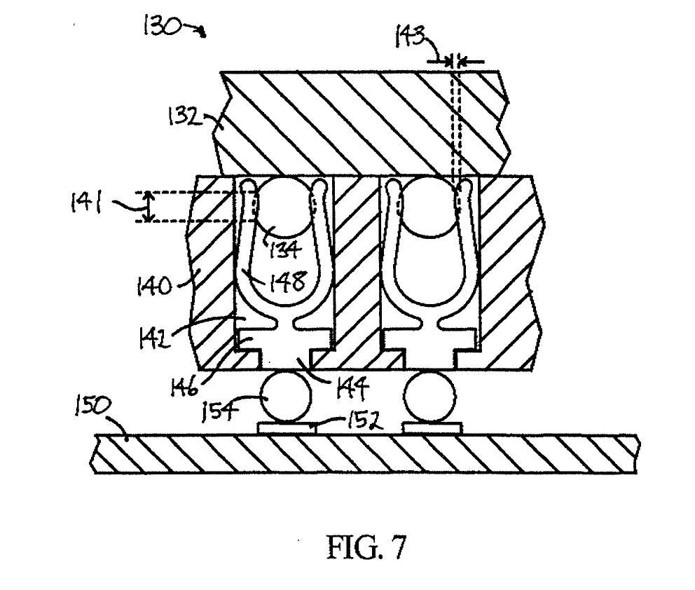

FIG. 7 is a cross-sectional view of an electronic system 130 comprising an IC package 132, a substrate or socket 140, and a secondary substrate or motherboard 150, in accordance with one embodiment of the invention. IC package 132, of which only a fragment is shown, can be the same as or similar to IC package 100 shown in FIGS. 3-6. IC package 132 comprises a plurality of conductive balls 134 of a relatively hard conductive material. In one embodiment, conductive balls 134 are formed of copper coated with approximately 30 micro-inches (0.762 micrometers) of gold over approximately 150 micro-inches (3.81 micrometers) of nickel.

Socket 140 comprises a plurality of openings 142, which can be formed in any suitable manner, such as drilling, machining, or molding. In each opening 142 is situated an electrically conductive receptacle 148. In one embodiment, receptacles 148 are formed of a beryllium-copper alloy coated with approximately 30 micro-inches (0.762 micrometers) of gold over approximately 150 micro-inches (3.81 micrometers) of nickel. However, receptacles 148 could comprise other suitable materials, such as beryllium, brass, copper, magnesium, silicon, steel, a phosphor-bronze alloy, or the like.

By providing balls 134 of relatively hard material and/or by providing a gold-to-gold contact between balls 134 and receptacles 148, the problem of cold flow experienced with solder balls in the socketable IC package disclosed in U.S. Pat. No. 6,045,416, mentioned earlier, is substantially reduced if not eliminated. The gold-to-gold contact inhibits galvanic corrosion.

In one embodiment, each receptacle 148 comprises a plurality of contact fingers. Any number of contact fingers can be employed, although typically the number of fingers ranges from 2 to 4 per receptacle 148. However, it is not essential that receptacle 148 comprise fingers, and receptacle 148 could alternatively be formed in some other suitable configuration to receive a conductive ball 134, e.g. in an expandable or resilient material into which ball 134 could be pressed.

The receptacles 148 require a minimum of vertical insertion force for the insertion or removal of balls 134. By minimizing the vertical insertion force, torsion stresses on the IC package 132 are reduced. Unless such stresses are minimized, stiffening structure may be required on IC package 132, contributing to its overall thickness and weight. Alternatively, a special insertion tool may be required. Through the reduction of vertical insertion and extraction forces, such stiffening structure and the need for a special insertion tool may be reduced or eliminated.

Each receptacle 148, in this embodiment, comprises a shoulder 146 resting on a corresponding portion of opening 142 within socket 140. Receptacles 148 could be press-fitted into openings 142, with or without the application of heat, depending upon the type of material. Each receptacle 148 further comprises a terminal portion 144 that is exposed from the lower surface of socket 140. Terminal portions 144 can be electrically and physically coupled to corresponding pads 152 of motherboard 150 through any suitable connectors, such as solder balls 134.

As seen from FIG. 7, when balls 134 are fully seated within receptacles 148, the tips of receptacles 148 extend beyond the centerlines of balls 134 and exert lateral and downward forces on balls 134.

To provide proper “wipe” between the contact surfaces of balls 134 and receptacles 148, the receiving end of receptacle, such as the tips of a plurality of fingers, deflect a certain distance, as indicated by deflection 143. In one embodiment, deflection 143 is approximately 0.003 inch per side (0.076 mm), but smaller or larger amounts of deflection could be used. As a ball 134 is inserted into the receiving end of a receptacle 148, the contact surface of the ball 134 is wiped by the contact surface(s) of the receptacle 148 over a certain distance, as indicated by wipe 141. A suitable wipe offers electrical advantages, by removing or diminishing the presence of contaminants from the contact surfaces. In one embodiment, wipe 141 is approximately 0.014 inch (0.355 mm), but smaller or larger wipes could be used.

In addition, the receiving end of receptacle 148 can be suitably formed to provide a relatively large area of contact between receptacle 148 and ball 134. This provides a substantially gas-tight seal between the contact surface of ball 134 and the contact surface of receptacle 148. A gas-tight seal offers reliability advantages, by preventing or reducing the intrusion of gas-borne contaminants that, over time, diminish the quality of the electrical connection between ball 134 and receptacle 148, resulting in high-resistance connections or opens.

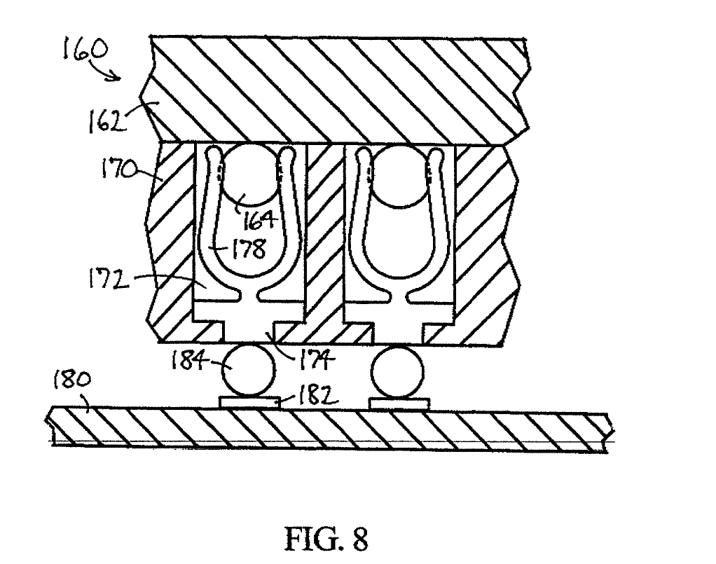

FIG. 8 is a cross-sectional view of an electronic system 160 comprising an IC package 162, a substrate or socket 170, and a secondary substrate or motherboard 180, in accordance with another embodiment of the invention. IC package 162, of which only a fragment is shown, can be the same as or similar to IC package 100 shown in FIGS. 3-6. IC package 162 comprises a plurality of conductive balls 164 of a relatively hard conductive material. Conductive balls 164 can be similar to conductive balls 134 shown in FIG. 7.

In the embodiment shown in FIG. 8, socket 170 is formed by molding it around conductive receptacles 178, which can be of the same general shape and composition as receptacles 148 of FIG. 7. Receptacles 178 are located within openings 172. Receptacles 178 are secured within socket 170 by molding socket 170 around receptacles 178. This can be done, for example, by inserting a shield (not shown) around each receptacle 178 during the molding process, and removing the shield after molding. The shield ensures that a suitably sized opening 172 remains around receptacle 178 to allow the ends of receptacle 178 to deflect upon insertion and removal of ball 164. Any other suitable fabrication method could be used. For example, the shields could be left in place following molding.

Each receptacle 178 comprises a terminal portion 174 that is exposed from the lower surface of socket 170. Terminal portions 174 can be electrically and physically coupled to corresponding pads 182 of motherboard 180 through any suitable connectors, such as solder balls 184.

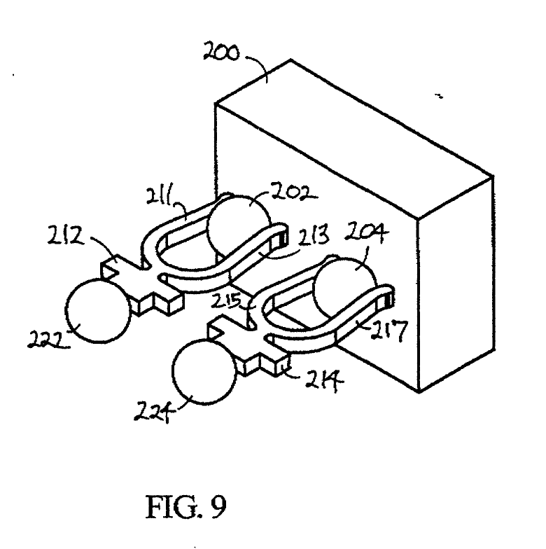

FIG. 9 is a perspective view of two balls 202 and 204 of a socketable IC package 200 coupled to a pair of receptacles 212 and 214, respectively, of a socket apparatus (not shown) in accordance with one embodiment of the invention. IC package 200, of which only a fragment is shown, can be the same as or similar to IC package 100 shown in FIGS. 3-6. IC package 200 comprises a plurality of conductive balls, such as balls 202 and 204, which can be of the same composition as balls 134 shown in FIG. 7.

In FIG. 9, the socket material normally surrounding receptacles 212 and 214 has been eliminated for ease of understanding. As seen in FIG. 9, each receptacle 212 comprises a pair of fingers 211 and 213 to receive ball 202. Receptacle 212 can further comprise a suitable connector, such as conductive ball 222, to couple the socket to an underlying substrate, such as a PCB or motherboard (not shown). In one embodiment, conductive ball 222 is a solder ball; however, other types of connectors could be employed, as mentioned earlier.

Similarly, each receptacle 214 comprises a pair of fingers 215 and 217 to receive ball 204. Receptacle 214 can further comprise a suitable connector, such as conductive ball 224, to couple the socket to an underlying substrate.

Receptacles, such as receptacles 212 and 214, can be fabricated in any suitable manner. In one embodiment, the receptacles are stamped from a sheet of metal.

FIG. 10 is a perspective view of several receptacles 231-234 and a substrate or socket 240, in accordance with one embodiment of the invention. Only a fragment of socket 240 is shown, as it will be understood that a single socket 240 can include thousands of receptacles 231-234 to receive a corresponding number of relatively hard conductive balls on the underside of an IC package.

Receptacles 231-234 are shown floating above socket 240 for ease of illustration. Normally, receptacles 231-234 will be moved in the direction of arrows 236 and suitably affixed within socket 240, as described earlier.

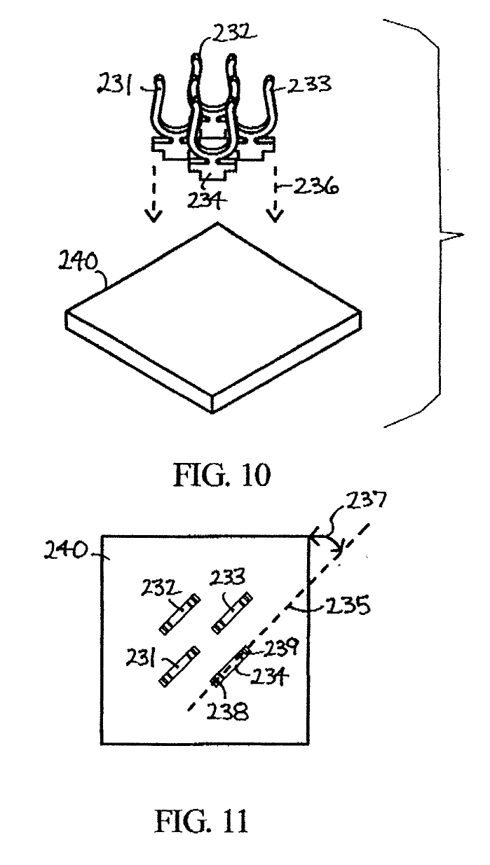

FIG. 11 is a top view of several receptacles 231-234 partially embedded within a substrate or socket 240, in accordance with one embodiment of the invention. From the embodiment of FIG. 11 will be seen one possible orientation of receptacles on a socket, in which receptacles 231-234 are positioned diagonally on socket 240 in order to increase the density of receptacles per unit area of the upper surface of socket 240.

In this embodiment, each receptacle, such as receptacle 234, has only two fingers, such as opposed fingers 238 and 239. All receptacles in a group of adjacent receptacles are angled so that the fingers of adjoining receptacles do not touch. For example, a straight line 235 drawn through fingers 238 and 239 makes an angle 237 with an edge (or a line parallel to an edge) of socket 240 (it is assumed that socket 240 has orthogonal edges). Angle 237 is not critical and can range between approximately 20 and 70 degrees. In the embodiment shown in FIG. 11, angle 237 is approximately 45 degrees for each receptacle 231-234; however, in other embodiments, angle 237 can be different for different groups of receptacles or even for different adjoining receptacles, so long as the fingers of adjoining receptacles do not touch.

FIG. 12 is a perspective view of a three-pronged receptacle 250, in accordance with one embodiment of the invention. Receptacle 250 comprises three prongs or fingers 253-255. Although fingers 253-255 are illustrated as being of approximately equal length and spaced at approximately equal angles of 120 degrees, they could be of unequal lengths and/or spaced at unequal angles in a different embodiment. Receptacle 250 further comprises a terminal portion 252 to electrically and physically couple receptacle 250 to a corresponding pad of an underlying substrate (not shown), such as a PCB or motherboard through any suitable connectors (not shown), such as solder balls.

Receptacle 250 can be fabricated in any suitable manner. In one embodiment, a plurality of receptacles like receptacle 250 are first stamped from a sheet of metal, and the fingers are subsequently bent in the desired orientation using, for example, a progressive die in a series of forming operations.

FIG. 13 is a perspective view of a four-pronged receptacle 260, in accordance with one embodiment of the invention. Receptacle 260 comprises four prongs or fingers 263-266. Although fingers 263-266 are illustrated as being of approximately equal length and spaced at approximately equal angles of 90 degrees, they could be of unequal lengths and/or spaced at unequal angles in a different embodiment. Receptacle 260 further comprises a terminal portion 262 to electrically and physically couple receptacle 260 to a corresponding pad of an underlying substrate (not shown), such as a PCB or motherboard through any suitable connectors (not shown), such as solder balls. Receptacle 260 may be fabricated in a manner similar to that described above regarding receptacle 250.

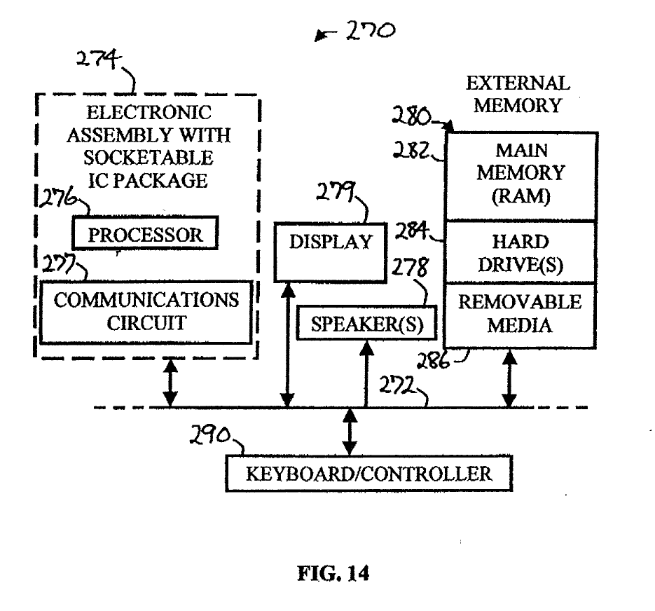

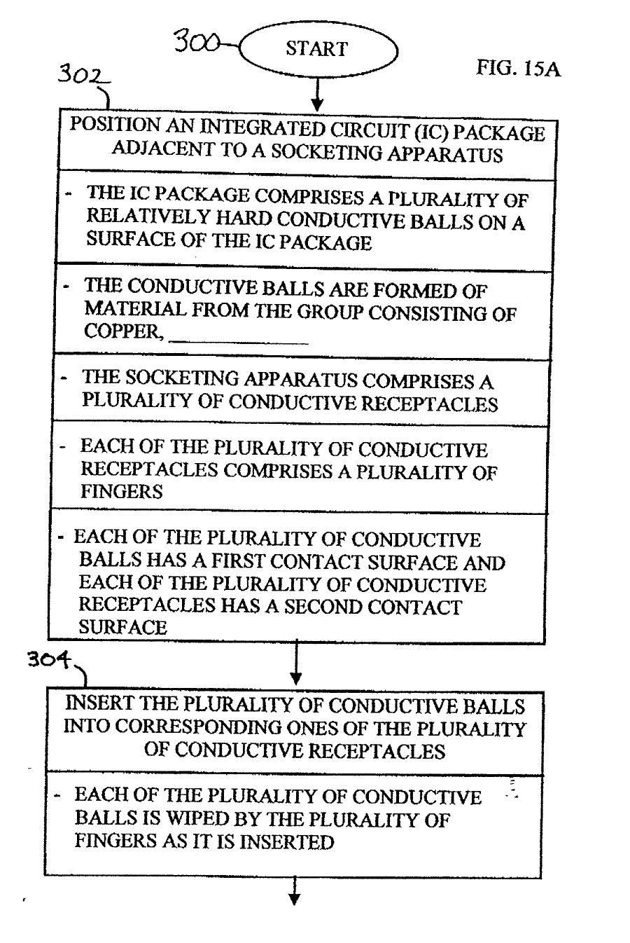

FIG. 14 is a block diagram of an electronic system 270 incorporating at least one electronic assembly 274 with a socketable IC package in accordance with one embodiment of the invention. Electronic assembly 274 has a reduced thickness and bulk.

Electronic system 270 is merely one example of an electronic system in which embodiments of the present invention can be used. In this example, electronic system 270 comprises a data processing system that includes a system bus 272 to couple the various components of the system. System bus 272 provides communications links among the various components of the electronic system 270 and can be implemented as a single bus, as a combination of busses, or in any other suitable manner.

Electronic assembly 274 is coupled to system bus 272. Electronic assembly 274 can include any circuit or combination of circuits. In one embodiment, electronic assembly 274 includes a processor 276 which can be of any type. As used herein, “processor” means any type of computational circuit such as, but not limited to, a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), or any other type of processor or processing circuit.

Other types of circuits that can be included in electronic assembly 274 are a custom circuit, an application-specific integrated circuit (ASIC), or the like, such as, for example, one or more circuits (such as a communications circuit 277) for use in wireless devices like cellular telephones, pagers, portable computers, two-way radios, and similar electronic systems. Electronic assembly 274 can perform any other type of function.

Electronic system 270 can also include an external memory 280, which in turn can include one or more memory elements suitable to the particular application, such as a main memory 282 in the form of random access memory (RAM), one or more hard drives 284, and/or one or more drives that handle removable media 286 such as floppy diskettes, compact disks (CDs), digital video disk (DVD), and the like.

Electronic system 270 can also include a display device 279, one or more speakers 278, and a keyboard and/or controller 290, which can include a mouse, trackball, game controller, microphone, voice-recognition device, or any other device that permits a system user to input information into and receive information from the electronic system 270.

Among various embodiments, system 270 could be a single or multi-processor machine, portable computer, laptop computer, handheld device (e.g., Personal Digital Assistant (PDA), palm-top computer, notebook computer, electronic book, or the like), cellular telephone, pager, personal entertainment device (e.g. digital music player), one-way or two-way radio, hearing aid, pacemaker, wristwatch, Internet appliance, or the like.

However, many other different embodiments can also take advantage of the relatively low stack height and relatively low weight and bulk of electronic packaging provided by the present disclosure.

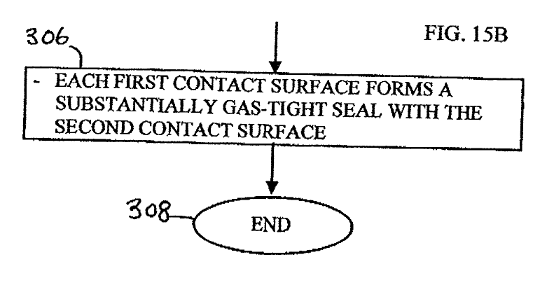

FIGS. 15A and 15B together constitute a flow diagram illustrating methods of fabricating an electronic assembly comprising relatively hard conductive balls, in accordance with one or more embodiments of the invention. The methods start at 300.

In 302, an IC package is positioned adjacent to a socketing apparatus, also referred to herein as a socket. The IC package comprises a plurality of relatively hard, conductive balls disposed on a surface of the IC package. The conductive balls are formed of material having a minimum Rockwell hardness of B-45. The socketing apparatus comprises a plurality of conductive receptacles, each of which comprises a plurality of fingers. Each of the plurality of conductive balls has a first contact surface (or multiple first contact surfaces), and each of the plurality of conductive receptacles has a second contact surface (or multiple second contact surfaces).

In 304, the plurality of conductive balls are inserted into corresponding ones of the plurality of conductive receptacles. As it is inserted, each of the plurality of conductive balls is wiped by the plurality of fingers.

In 306, each first contact surface forms a substantially gas-tight seal with the second contact surface.

The methods end at 308.

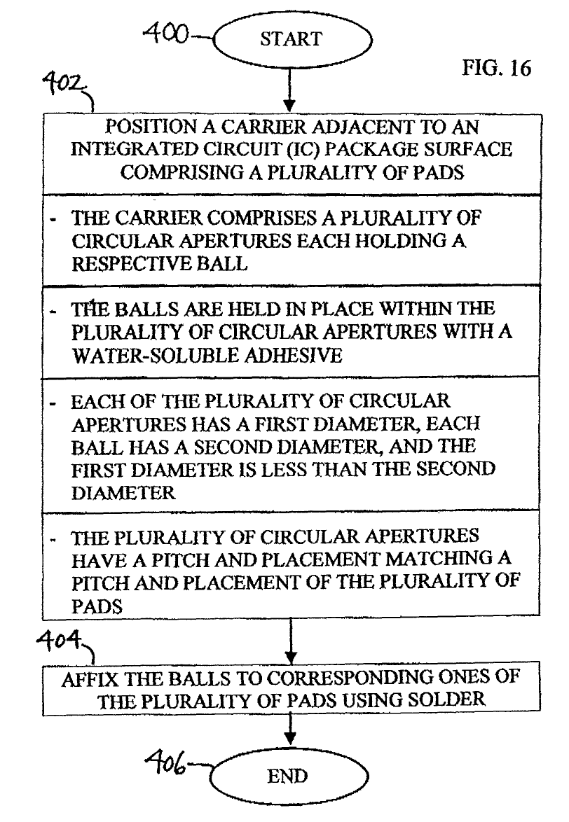

FIG. 16 is a flow diagram illustrating methods of positioning a plurality of conductive balls on an IC package, in accordance with one or more embodiments of the invention. The methods start at 400.

In 402, a carrier is positioned adjacent to an IC package surface comprising a plurality of terminals or pads. The carrier comprises a plurality of circular apertures each holding a respective ball. The balls can be held in place within the plurality of circular apertures with a water-soluble adhesive. Each of the plurality of circular apertures has a first diameter; each ball has a second diameter; and the first diameter is less than the second diameter. The plurality of circular apertures have a pitch and placement matching the pitch and placement of the plurality of pads.

In 404, the balls are affixed to the corresponding ones of the plurality of pads using a suitable adhesive, such as solder.

The methods end at 406.

The operations described above with respect to the methods illustrated in FIGS. 15A, 15B, and 16 can be performed in a different order from those described herein. Also, it will be understood that while an “end” block is shown in FIGS. 15B and 16, these methods can be performed continuously in a manufacturing environment.

### Conclusion

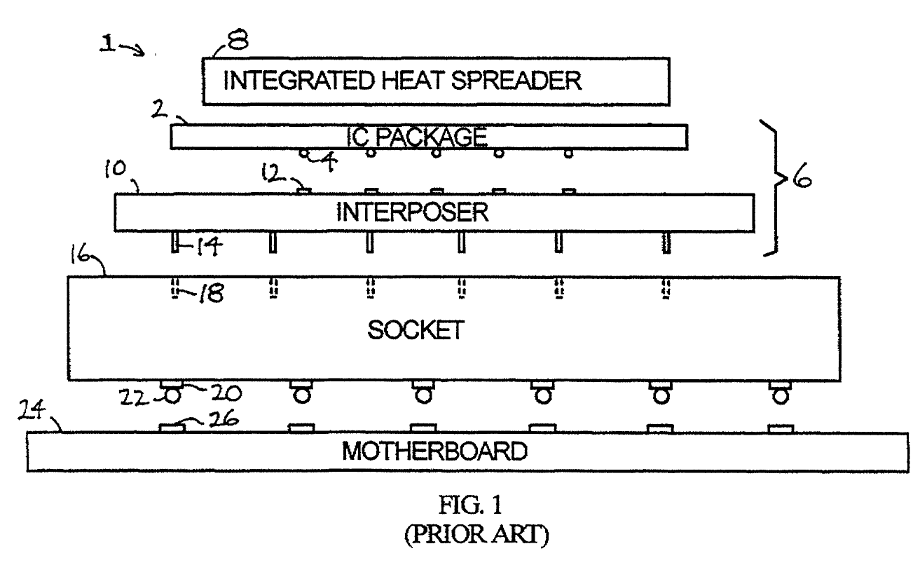

Embodiments of the present invention provide for a lightweight electronic package, and for methods of manufacture thereof, that minimize the thickness and bulk of the package. Loop inductance of the interconnect is also reduced, because conductive paths between the IC package and the motherboard are shorter than they would be through a conventional socketable package that includes an interposer. In addition, conductive balls have a higher current carrying capacity and are more rugged than pins, as used in the prior art socketable electronic assembly shown in FIG. 1

An electronic system and/or data processing system that incorporates one or more electronic assemblies that utilize the concepts disclosed herein can be produced in configurations having reduced thickness and weight, and with enhanced electronic performance, and such systems are therefore more commercially attractive.

As shown herein, the present invention can be implemented in a number of different embodiments, including an IC package, an electronic assembly, an electronic system or data processing system, one or more methods of fabricating an electronic assembly, and one or more methods of affixing a plurality of balls to an IC package surface. Other embodiments will be readily apparent to those of ordinary skill in the art. The elements, materials, geometries, dimensions, and sequence of operations can all be varied to suit particular packaging requirements.

FIGS. 1 through 13 are merely representational and are not drawn to scale. Certain proportions thereof may be exaggerated, while others may be minimized. FIGS. 2-16 are intended to illustrate various embodiments of the invention that can be understood and appropriately carried out by those of ordinary skill in the art.

While certain structures or operations have been described herein relative to the reader's perspective, such as “top” or “bottom”, “upper” or “lower”, “left” or “right”, “front” or “rear”, and so forth, it will be understood that these descriptors are relative, and that they would be reversed if the particular structure being described (e.g. an IC package, socket, carrier, etc.) were inverted, rotated, or viewed in mirror-image. Therefore, these terms are not intended to be limiting.

Although specific embodiments have been illustrated and described herein, it will be appreciated by those of ordinary skill in the art that any arrangement or process that is calculated to achieve the same purpose may be substituted for the specific embodiments shown. This application is intended to cover any adaptations or variations of embodiments of the present invention. Therefore, it is manifestly intended that embodiments of this invention be limited only by the claims and the equivalents thereof.

It is emphasized that the Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description of Embodiments of the Invention, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description of Embodiments of the Invention, with each claim standing on its own as a separate preferred embodiment.

What is claimed is:

1. An integrated circuit (IC) package comprising:
a die having a plurality of terminals; and
a plurality of relatively hard conductive balls on a surface of the IC package, each conductive ball being coupled to a respective one of the plurality of terminals.

2. The IC package recited in claim 1, wherein each of the plurality of conductive balls comprises material from the group consisting of aluminum, copper, magnesium, molybdenum, platinum, silver, zinc, alloys comprising the foregoing metals, steel, and a phosphor-bronze alloy.

3. The IC package recited in claim 1, wherein each of the plurality of conductive balls comprises at least one coating from the group consisting of cobalt, gold, nickel, palladium, and silver.

4. The IC package recited in claim 1, wherein each of the plurality of conductive balls is coupled to the respective one of the plurality of terminals through solder.

5. An electronic assembly comprising:
an integrated circuit (IC) package including a die having a plurality of terminals, and a plurality of copper balls on a surface of the IC package, each copper ball being coupled to a respective one of the plurality of terminals; and
a socket including a plurality of conductive receptacles, each receptacle receiving a respective copper ball.

6. The electronic assembly recited in claim 5, wherein the socket comprises an insulating member having first and second surfaces, wherein the plurality of conductive receptacles are on the first surface, and wherein the socket further comprises a plurality of terminals on the second surface, each terminal being electrically coupled to a respective one of the plurality of conductive receptacles.

7. The electronic assembly recited in claim 5, wherein each receptacle has a number of fingers from the group consisting of two, three, and four.

8. The electronic assembly recited in claim 5, wherein each of the plurality of copper balls comprises at least one coating from the group consisting of cobalt, gold, nickel, palladium, and silver.

9. The electronic assembly recited in claim 5, wherein each of the plurality of copper balls has a first contact surface, wherein each of the plurality of receptacles has a second contact surface, and wherein an area of contact between the first and second contact surfaces forms a substantially gas-tight seal.

10. The electronic assembly recited in claim 5, wherein the plurality of receptacles comprise material from the group consisting of beryllium, brass, copper, magnesium, silicon, steel, a beryllium-copper alloy, and a phosphor-bronze alloy.

11. A data processing system comprising:
a bus coupling components in the data processing system;
a display coupled to the bus;
a memory coupled to the bus; and
a processor coupled to the bus and comprising an electronic assembly including,
an integrated circuit (IC) package including a die having a plurality of terminals, and a plurality of copper balls on a surface of the IC package, each copper ball being coupled to a respective one of the plurality of terminals; and
a socket including a plurality of conductive receptacles, each receptacle to receive a respective copper ball.

12. The data processing system recited in claim 11, wherein the socket comprises an insulating member having first and second surfaces, wherein the plurality of conductive receptacles are on the first surface, and wherein the socket further comprises a plurality of terminals on the second surface, each terminal being electrically coupled to a respective one of the plurality of conductive receptacles.

13. The data processing system recited in claim 11, wherein each receptacle has a number of fingers from the group consisting of two, three, and four.

14. The data processing system recited in claim 11, wherein each of the plurality of copper balls comprises at least one coating from the group consisting of cobalt, gold, nickel, palladium, and silver.

15. A socketing apparatus to mount an integrated circuit (IC) package comprising:
an insulating member having a first surface;
a plurality of conductive receptacles on the first surface, each receptacle having a plurality of fingers forming an enclosure to receive a relatively hard conductive ball.

16. The socketing apparatus recited in claim 15, wherein the insulating member further comprises a second surface, and a plurality of terminals on the second surface, each terminal electrically coupled to a respective one of the plurality of conductive receptacles.

17. The socketing apparatus recited in claim 15, wherein each receptacle has a number of fingers from the group consisting of two, three, and four.

18. The socketing apparatus recited in claim 15, wherein the first surface has orthogonal edges, wherein each receptacle has only two fingers, and wherein a line drawn through the two fingers forms an angle with an edge of the first surface within the range of 20 to 70 degrees.

19. An assembly aid to facilitate affixing a plurality of balls of uniform diameter to a plurality of pads of an integrated circuit (IC) package, the assembly aid comprising a planar member having a plurality of circular apertures of uniform diameter less than the diameter of the metal balls.

20. The assembly aid recited in claim 19, wherein the planar member is formed of a polyimide material.

21. The assembly aid recited in claim 19, wherein the plurality of circular apertures have a pitch and placement that match a pitch and placement of the plurality of pads of the IC package.

22. The assembly aid recited in claim 19, wherein each of the plurality of circular apertures has an adhesive coating.

23. A method comprising:
positioning an integrated circuit (IC) package adjacent to a socketing apparatus, the IC package comprising a plurality of relatively hard conductive balls on a surface of the IC package, the socketing apparatus comprising a plurality of conductive receptacles; and
inserting the plurality of conductive balls into corresponding ones of the plurality of conductive receptacles.

24. The method recited in claim 23 wherein, in positioning, each of the plurality of conductive receptacles comprises a plurality of fingers, and wherein, in inserting, each of the plurality of conductive balls is wiped by the plurality of fingers as it is inserted.

25. The method recited in claim 23 wherein, in positioning, each of the plurality of conductive balls has a first contact surface and each of the plurality of conductive receptacles has a second contact surface, and wherein, in inserting, each of the first contact surfaces forms a substantially gas-tight seal with the second contact surface.

26. The method recited in claim 23 wherein, in positioning, the conductive balls are formed of material from the group consisting of aluminum, copper, magnesium, molybdenum, platinum, silver, zinc, alloys comprising the foregoing metals, steel, and a phosphor-bronze alloy.

27. A method comprising:
positioning a carrier adjacent to an integrated circuit (IC) package surface comprising a plurality of pads, the carrier comprising a plurality of circular apertures each holding a respective ball, the plurality of circular apertures having a pitch and placement matching a pitch and placement of the plurality of pads; and
affixing the balls to corresponding ones of the plurality of pads.

28. The method recited in claim 27 wherein, in affixing, the balls are coupled to the corresponding ones of the plurality of pads using solder.

29. The method recited in claim 27 wherein, in positioning, each of the plurality of circular apertures has a first diameter, each ball has a second diameter, and the first diameter is less than the second diameter.

30. The method recited in claim 27 wherein, in positioning, the balls are held in place within the plurality of circular apertures with an adhesive.

31. The method recited in claim 30 wherein, in positioning, the adhesive is a water-soluble adhesive.
